(19) United States
(12) Patent Application Publication
(10) Pub. No.: US 2015/0118832 A1
(43) Pub. Date: Apr. 30, 2015

(54) METHODS FOR PATTERNING A HARDMASK LAYER FOR AN ION IMPLANTATION PROCESS

(71) Applicant: Applied Materials, Inc., Santa Clara, CA (US)

(72) Inventors: Bingxi Sun WOOD, Cupertino, CA (US); Li Yan MIAO, San Francisco, CA (US); Huixiong DAI, San Jose, CA (US); Adam BRAND, Palo Alto, CA (US); Yongmei CHEN, San Jose, CA (US); Mandar B. PANDIT, Santa Clara, CA (US); Qingjun ZHOU, San Jose, CA (US)

(21) Appl. No.: 14/062,638

(22) Filed: Oct. 24, 2013

(51) Int. Cl. H01L 21/266; H01L 21/3105

(52) U.S. Cl. CPC H01L 21/266; H01L 21/31053
USPC 438/514; 438/702

(57) ABSTRACT

Embodiments of the present invention provide a methods for patterning a hardmask layer with good process control for an ion implantation process, particularly suitable for manufacturing the fin field effect transistor (FinFET) for semiconductor chips. In one embodiment, a method of patterning a hardmask layer disposed on a substrate includes forming a planarization layer over a hardmask layer disposed on a substrate, disposing a patterned photoresist layer over the planarization layer, patterning the planarization layer and the hardmask layer uncovered by the patterned photoresist layer in a processing chamber, exposing a first portion of the underlying substrate, and removing the planarization layer from the substrate.

### BACKGROUND

1. Field

Embodiments of the present invention generally relate to methods for patterning a hardmask layer used in a fin field effect transistor (FinFET), and more particularly to methods for patterning a hardmask layer utilized during an ion implantation process in fin field effect transistor (FinFET) semiconductor applications.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of device structures on the substrate is important to VLSI and ULSI success and to the continued effort to increase circuit density and quality of individual substrates and die.

A patterned mask, such as a photoresist layer or a hardmask layer, is commonly used in forming structures, such as gate structure, implant region definition, shallow trench isolation (STI), bite lines and the like, on a substrate by etching process. The patterned mask is conventionally fabricated by using a lithographic process to optically transfer a pattern having the desired critical dimensions to a layer of photoresist or a hardmask layer. For example, the photoresist layer is then developed to remove undesired portion of the photoresist, thereby creating openings in the remaining photoresist. In the case an additional hardmask layer is utilized, the hardmask layer can then further be etched/patterned using openings formed in the remaining photoresist as an etching mask.

In order to enable fabrication of next generation devices and structures, fin field effect transistors (FinFET) architecture utilized to improve performance of the transistors. In particular, fin field effect transistors (FinFET) architecture is utilized to improve gate control over channels so as to improve device performance so that higher density of the semiconductor devices may be obtained. By utilizing the fin field effect transistors (FinFET) architecture, multiple transistors may be placed in the integrated circuits (ICs) very close to each other.

FIG. 1A depicts an exemplary embodiment of a fin field effect transistor (FinFET) 150 disposed on a substrate 100. The substrate 100 may be a silicon substrate, a germanium substrate, or a substrate formed from other semiconductor materials. In one embodiment, the substrate 100 may include p-type or n-type dopants doped therein. The substrate 100 includes a plurality of semiconductor fins 102, 152 formed thereon isolated by shallow trench isolation (STI) structures 104. The substrate 100 may includes a portion in NMOS device region 101 and a portion in PMOS device region 103, and each of the semiconductor fins 102, 152 may be sequentially and alternatively formed in the NMOS device region 101 and the PMOS device region 103 in the substrate 100. The semiconductor fins 102, 152 are formed above the top surfaces of the shallow trench isolation (STI) structures 104. Subsequently, a gate structure 106, typically including a gate electrode layer disposed on a gate dielectric layer, is deposited on both of the NMOS device region 101 and the PMOS device region 103 and over the semiconductor fins 102, 152.

The gate structure 106 may be patterned to expose portions 148, 168 of the semiconductor fins 102, 152 uncovered by the gate structure 106. The exposed portions 148, 168 of the semiconductor fins 102, 152 may then be doped with dopants to form halo and source and drain extension regions by an implantation process.

FIG. 1B depicts a cross sectional view of the substrate 100 including the plurality of semiconductor fins 102, 152 formed on the substrate 100 isolated by the shallow trench isolation (STI) structures 104. During an implantation process, ions, as shown by arrows 112, may be desired only to be implanted into the semiconductor fins 152 located in the PMOS device region 103, for example, or vice versa. In such case, other regions, such as the semiconductor fins 102 located in the NMOS device region 101, may be protected by a hardmask layer 114, as shown in FIG. 1B, to prevent the dopants from penetrating into the semiconductor fins 102 located in the NMOS device region 101. However, selectively forming the hardmask layer 114 on only certain region of the substrate 100 may increase the complexity of process. Typically, the hardmask layer 114 is patterned to remove a portion of the hardmask layer 114 from the substrate 100 so as to expose some portions of the substrate 100 for implantation. However, as the designs of the fin field effect transistor (FinFET) 150 is pushed up against the technology limits for the structure geometry, the need for accurate process control for the manufacture of small critical dimensional structures with thin layer and structure control has become increasingly important. Conventional process for patterning the hardmask layer 114 often have poor etching stop control and low selectivity, thereby damaging the substrate structure even prior to the ion implantation process. Additionally, as the hardmask layer 114 is formed on an uneven upper surface, including the protruding semiconductor fins 102, 152 formed on the substrate, the uneven upper surface of the substrate 100 often creates difficulty in accurately performing lithography and patterning. Furthermore, insufficient robustness of the hardmask layer 114 often result in the ions undesirably penetrating through the hardmask layer 114 into certain regions of the substrate, thereby contaminating the substrate 100 and eventually leading to device failure and poor electrical device performance.

Thus, there is a need for improved methods for patterning a hardmask layer suitable for an ion implantation process for fin field effect transistor (FinFET) or other semiconductor devices with accurate process control.

### SUMMARY

Embodiments of the present invention provide a methods for patterning a hardmask layer with good process control for an ion implantation process, particularly suitable for manufacturing fin field effect transistor (FinFET) for semiconductor chips. In one embodiment, a method of patterning a hardmask layer disposed on a substrate includes forming a planarization layer over a hardmask layer disposed on a substrate, disposing a patterned photoresist layer over the planarization layer, patterning the planarization layer and the hardmask layer uncovered by the patterned photoresist layer in a processing chamber, exposing a first portion of the underlying substrate, and removing the planarization layer from the substrate.

In another embodiment, a method of patterning a hardmask layer disposed on a substrate includes forming a hardmask layer on a substrate, wherein the substrate includes a plurality of semiconductor fins formed thereon isolated by a plurality of shallow trench isolation structures, forming a planarization layer over the hardmask layer disposed on a substrate to form a substantially planar upper surface on the planarization layer, and patterning the planarization layer and the hardmask layer utilizing a patterned photoresist layer disposed over the substantially planar upper surface on the planarization layer until a portion of the semiconductor fins formed on the substrate is exposed.

In yet another embodiment, a method of patterning a hardmask layer disposed on a substrate includes spin-coating a planarization layer over a hardmask layer on a substrate, wherein the substrate includes a plurality of semiconductor fins formed thereon isolated by a plurality of shallow trench isolation structures, anisotropically patterning a portion of the planarization layer and a portion of the hardmask exposed by a patterned photoresist layer disposed on the planarization layer to expose a portion of the semiconductor fins formed on the substrate, removing the planarization layer from the substrate exposing the hardmask layer remained on the substrate, and performing an ion implantation process utilizing the hardmask layer remained on the substrate as an ion implantation mask.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a schematic perspective view of a substrate having a fin field effect transistor (FinFET) structure formed thereon;

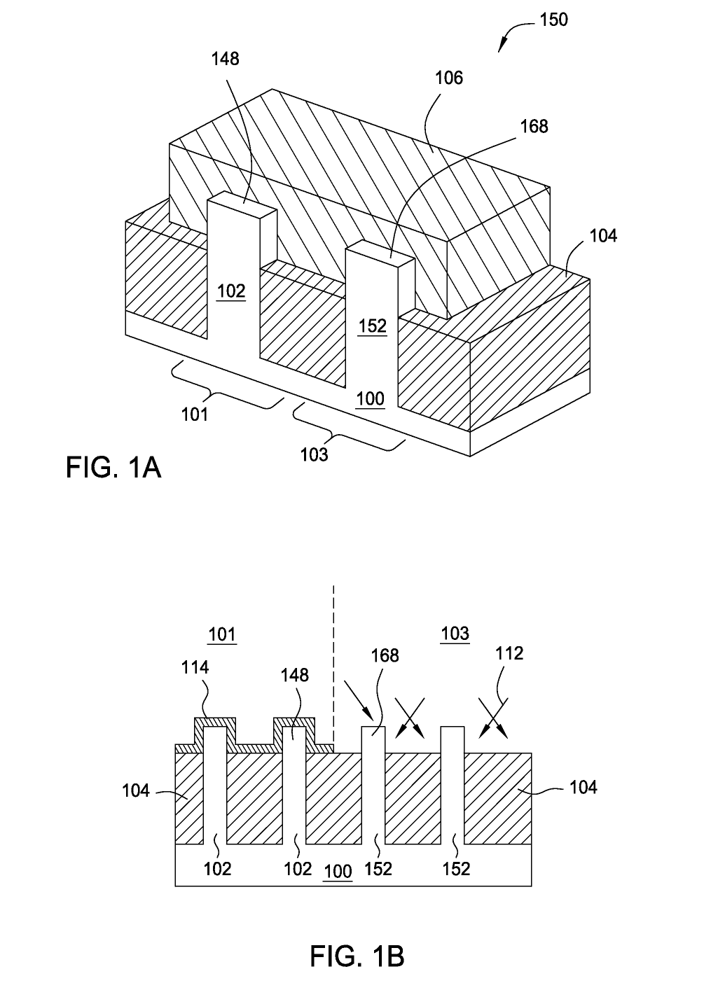

FIG. 1B depicts a cross sectional view of a substrate having a portion of the fin field effect transistor (FinFET) structure formed thereon;

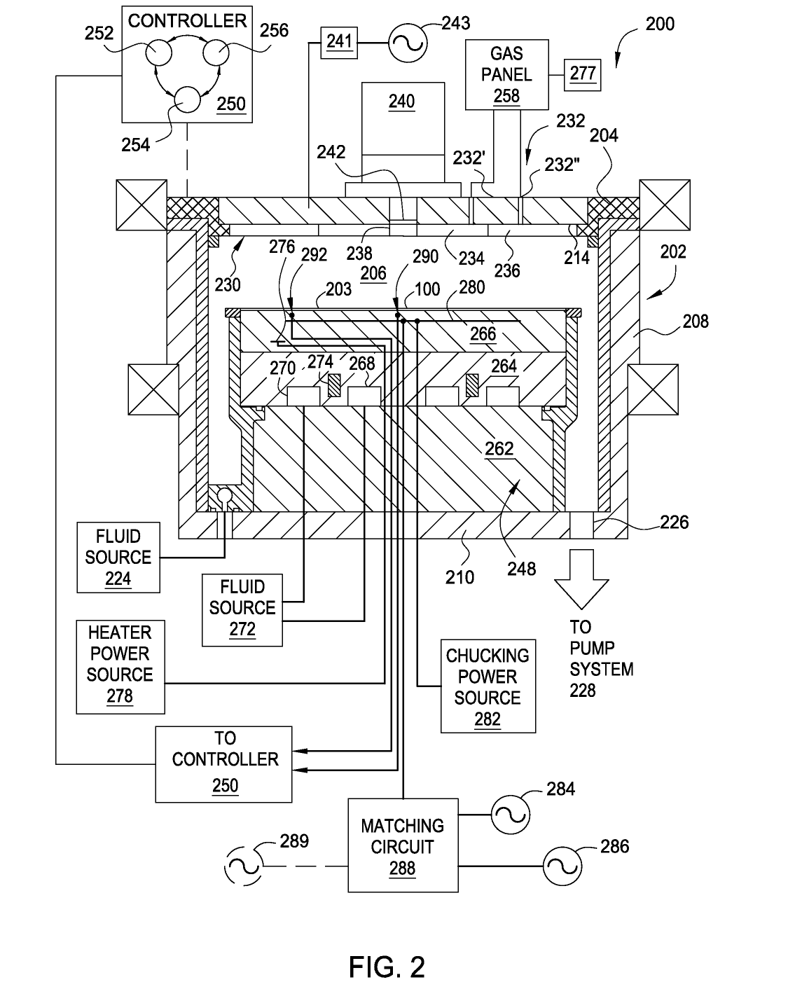

FIG. 2 depicts an apparatus utilized to perform a patterning process to pattern a hardmask layer;

FIG. 3 depicts a flow diagram of a method for patterning a hardmask layer using the apparatus of FIG. 2; and

FIG. 4A-4G depict one embodiment of a sequence for patterning a hardmask layer formed on a substrate suitable for using in an ion implantation process.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for patterning a hardmask layer that may be used for an ion implantation process, particularly for fin field effect transistor (FinFET) semiconductor structures. In one embodiment, the patterning process utilizes a planarization layer disposed above the hardmask layer to provide a substantially planar surface that facilitates performing a lithography process on the planarization layer. By utilizing an additional planarization layer disposed on the hardmask layer, more precise exposure may be realized during the lithography process. As such, a good control of an etching stop endpoint and etching selectivity may be obtained while removing a portion of the hardmask layer from the substrate with desired profile without damaging the substrate during subsequent etch processes.

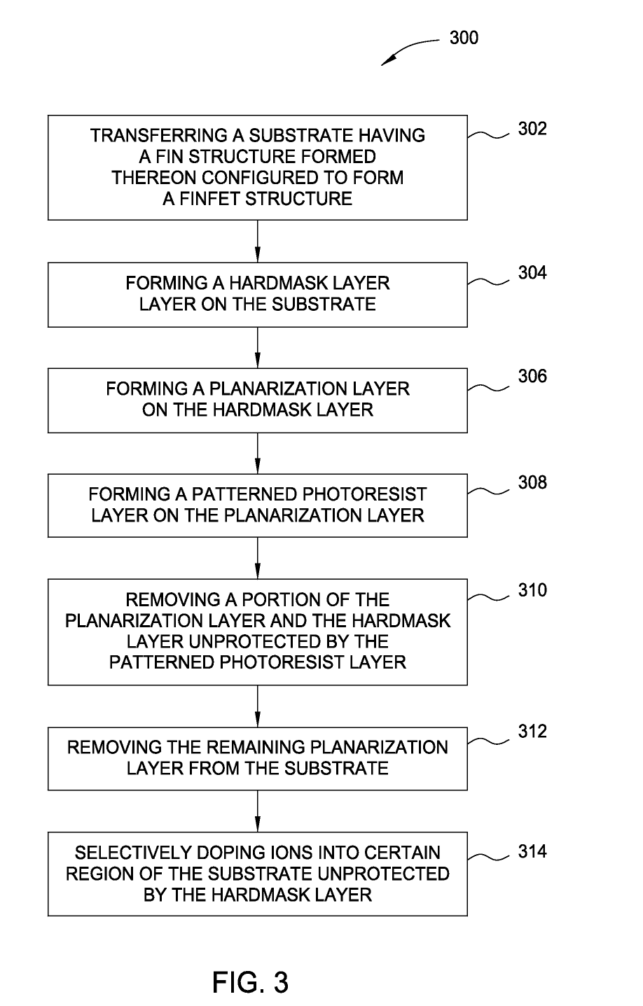

FIG. 2 is a sectional view of one embodiment of a processing chamber 200 suitable for performing a patterning process to etch a planarization layer along with a hardmask layer on a substrate using an anisotropic etching process. Suitable processing chambers that may be adapted for use with the teachings disclosed herein include, for example, a ENABLER® processing chamber available from Applied Materials, Inc. of Santa Clara, Calif. Although the processing chamber 200 is shown including a plurality of features that enable superior etching and trimming performance, it is contemplated that other processing chambers may be adapted to benefit from one or more of the inventive features disclosed herein.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in a sidewall 208 and a selectively sealed by a slit valve to facilitate entry and egress of a substrate 100 from the processing chamber 200. An exhaust port 226 is defined in the chamber body 202 and couples the interior volume 206 to a pump system 228. The pump system 228 generally includes one or more pumps and throttle valves utilized to evacuate and regulate the pressure of the interior volume 206 of the processing chamber 200. In one embodiment, the pump system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow excess to the interior volume 106 of the processing chamber 200. The lid 204 includes a window 242 that facilitates optical process monitoring. In one embodiment, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 100 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the embodiment depicted in FIG. 2, inlet ports 232′, 232″ are provided in the lid 204 to allow gases to be delivered from the gas panel 258 to the interior volume 206 of the processing chamber 200. In one embodiment, the gas panel 258 is adapted to provide fluorinated process gas through the inlet ports 232′, 232″ and into the interior volume 206 of the processing chamber 200. In one embodiment, the process gas provided from the gas panel 258 includes at least a fluorinated gas, chlorine, and a carbon containing gas, an oxygen gas, a nitrogen containing gas and a chlorine containing gas. Examples of fluorinated and carbon containing gases include CHF₃, CH₂F₂ and CF₄. Other fluorinated gases may include one or more of C₂F, C₄F₆, C₃F₈ and C₅F₈. Examples of the oxygen containing gas include O₂, CO₂, CO, N₂O, NO₂, O₃, H₂O, and the like. Examples of the nitrogen containing gas include N₂, NH₃, N₂O, NO₂ and the like. Examples of the chlorine containing gas include HCl, Cl₂, CCI₄, CHCl₃, CH₂Cl₂, CH₃Cl, and the like. Suitable examples of the carbon containing gas include methane (CH₄), ethane (C₂H₆), ethylene (C₂H₄), and the like.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 100 being processed in the processing chamber 200.

A remote plasma source 277 may be optionally coupled to the gas panel 258 to facilitate dissociating gas mixture from a remote plasma prior to entering into the interior volume 206 for processing. A RF source power 243 is coupled through a matching network 241 to the showerhead assembly 230. The RF source power 243 typically is capable of producing up to about 3000 W at a tunable frequency in a range from about 50 kHz to about 200 MHz.

The showerhead assembly 230 additionally includes a region transmissive to an optical metrology signal. The optically transmissive region or passage 238 is suitable for allowing the optical monitoring system 240 to view the interior volume 206 and/or the substrate 100 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240. In one embodiment, the passage 238 includes a window 242 to prevent gas leakage through the passage 238. The window 242 may be a sapphire plate, quartz plate or other suitable material. The window 242 may alternatively be disposed in the lid 204.

In one embodiment, the showerhead assembly 230 is configured with a plurality of zones that allow for separate control of gas flowing into the interior volume 206 of the processing chamber 200. In the embodiment FIG. 2, the showerhead assembly 230 as an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the gas distribution (showerhead) assembly 230. The substrate support pedestal assembly 248 holds the substrate 100 during processing. The substrate support pedestal assembly 248 generally includes a plurality of lift pins (not shown) disposed therethrough that are configured to lift the substrate 100 from the substrate support pedestal assembly 248 and facilitate exchange of the substrate 100 with a robot (not shown) in a conventional manner. An inner liner 218 may closely circumscribe the periphery of the substrate support pedestal assembly 248.

In one embodiment, the substrate support pedestal assembly 248 includes a mounting plate 262, a base 264 and an electrostatic chuck 266. The mounting plate 262 is coupled to the bottom 210 of the chamber body 202 includes passages for routing utilities, such as fluids, power lines and sensor leads, among others, to the base 264 and the electrostatic chuck 166. The electrostatic chuck 266 comprises at least one clamping electrode 280 for retaining the substrate 100 below showerhead assembly 230. The electrostatic chuck 266 is driven by a chucking power source 282 to develop an electrostatic force that holds the substrate 100 to the chuck surface, as is conventionally known. Alternatively, the substrate 100 may be retained to the substrate support pedestal assembly 248 by clamping, vacuum or gravity.

At least one of the base 264 or electrostatic chuck 266 may include at least one optional embedded heater 276, at least one optional embedded isolator 274 and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266 and ultimately, the temperature profile of the substrate 100 disposed thereon. The temperature of the electrostatic chuck 266 and the base 264 may be monitored using a plurality of temperature sensors 290, 292. The electrostatic chuck 266 may further comprise a plurality of gas passages (not shown), such as grooves, that are formed in a substrate support pedestal supporting surface of the chuck 266 and fluidly coupled to a source of a heat transfer (or backside) gas, such as He. In operation, the backside gas is provided at controlled pressure into the gas passages to enhance the heat transfer between the electrostatic chuck 266 and the substrate 100.

In one embodiment, the substrate support pedestal assembly 248 is configured as a cathode and includes an electrode 280 that is coupled to a plurality of RF power bias sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the embodiment depicted in FIG. 2, the dual RF bias power sources 284, 286 are coupled to the electrode 280 disposed in the substrate support pedestal assembly 248 through a matching circuit 288. The signal generated by the RF bias power 284, 286 is delivered through matching circuit 188 to the substrate support pedestal assembly 248 through a single feed to ionize the gas mixture provided in the plasma processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 100 is disposed on the substrate support pedestal assembly 248 in the plasma processing chamber 200. A process gas and/or gas mixture is introduced into the chamber body 202 through the showerhead assembly 230 from the gas panel 258. A vacuum pump system 228 maintains the pressure inside the chamber body 202 while removing deposition by-products.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing system 200 are handled through numerous signal cables.

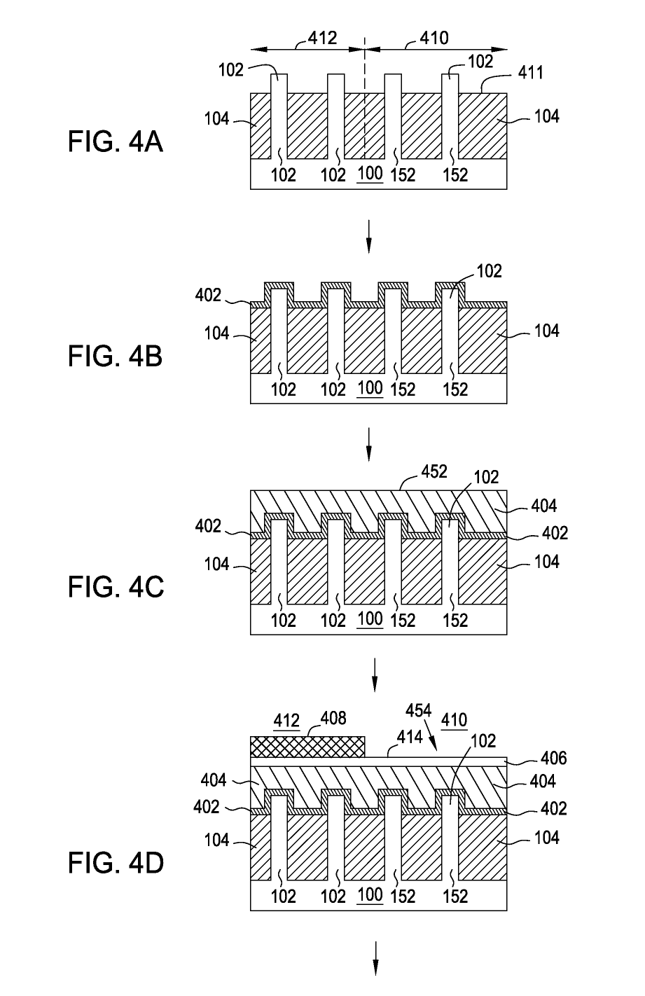

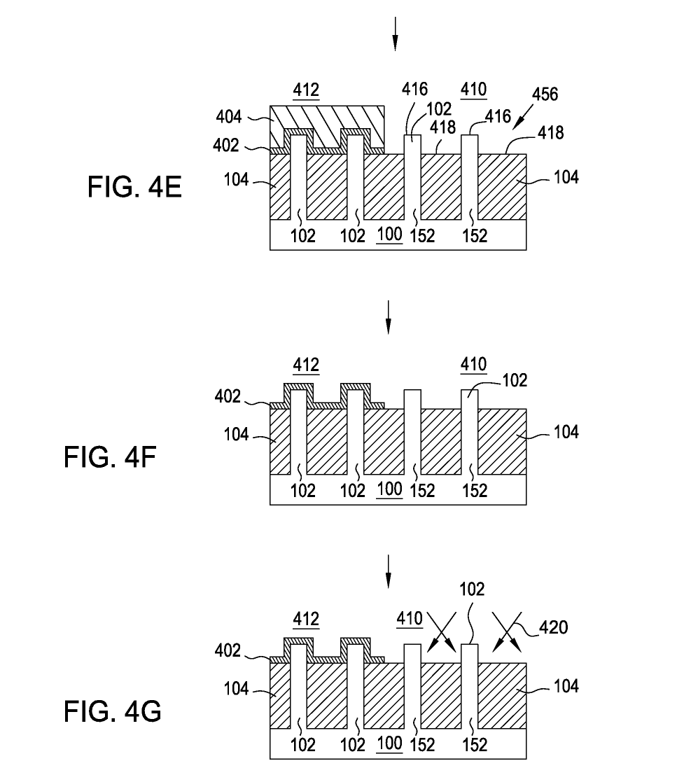

FIG. 3 is a flow diagram of one embodiment of a patterning process 300 that may be practiced in the chamber 200 or other suitable processing chamber. FIGS. 4A-4G are schematic cross-sectional views of a portion of a composite substrate corresponding to various stages of the process 300. The process 300 may be utilized to form a fin field effect transistor (FinFET) disposed on a substrate having dopants doped at different regions of the substrate for fin field effect transistor (FinFET) semiconductor devices. Alternatively, the process 300 may be beneficially utilized to etch other types of structures.

The process 300 begins at block 302 by transferring (i.e., providing) a substrate, such as the substrate 100, having a plurality of semiconductor fins 102, 152 formed thereon. As discussed above, the semiconductor fins 102, 152 may be isolated by shallow trench isolation (STI) structures 104. In one embodiment, the substrate 100 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 100 may have various dimensions, such as 200 mm, 300 mm, 450 mm or other diameter wafers, as well as, rectangular or square panels. Unless otherwise noted, embodiments and examples described herein are conducted on substrates with a 200 mm diameter, a 300 mm diameter, or a 450 mm diameter substrate. In the embodiment wherein a SOI structure is utilized for the substrate 100, the substrate 100 may include a buried dielectric layer disposed on a silicon crystalline substrate. In the embodiment depicted herein, the substrate 100 may be a crystalline silicon substrate.

The plurality of the semiconductor fins 102, 152 formed on the substrate 100 may be part of the substrate 100 extending upwards from the substrate 100 utilizing the shallow trench isolation (STI) structures 104 to isolate each of the semiconductor fins 102, 152. The semiconductor fins 102, 152 may be formed above the top surfaces 411 of the shallow trench isolation (STI) structures 104. In one embodiment, the semiconductor fins 102, 152 may be doped silicon layers, crystalline silicon layers, silicon germanium and group III-V materials or any suitable types of the silicon containing layers. In another embodiment, the semiconductor fins 102, 152 may be individually formed structure disposed on the substrate 100 using suitable techniques in the art. The shallow trench isolation (STI) structures 104 may be formed by an insulating material, such as a silicon oxide material or other dielectric layer.

In one embodiment, the substrate 100 may have a first-type doped device region 412, such as a n-type doped region, and a second-type doped device region 410, such as a p-typed doped region, formed therein to have the semiconductor fins 102, 152, adapted to have different types of dopants to be disposed therein. In one embodiment, the first type doped device region 412 may be a NMOS device region and the second type doped device region 412 may be a PMOS device region. In different regions 410, 412 of the substrate 100, different types of the dopants, such as p-type or n-type dopants, may be adapted to be doped therein to create doped regions having different conductivity. Details regarding how the dopants may be doped into different regions of the substrate 100 will be described in greater detail below.

At block 304, a hardmask layer 402 may be formed on the substrate 100, as shown in FIG. 4B. In one embodiment, the hardmask layer 402 may be formed conformally covering a substantially entire surface of the substrate 100. The hardmask layer 402 may serve as a mask layer to allow dopants only being implanted into certain regions of the substrate 100 while another portion of the substrate 100 is protected by the hardmask layer 402 during the ion implantation process.

In one embodiment, the hardmask layer 402 is an amorphous carbon layer with or without dopants doped therein. One example of the amorphous carbon layer may be an Advanced Patterning Film™ (APF) available from Applied Materials. Another example of a doped amorphous carbon layer may be an TOPAZ™ carbon hardmask layer available from Applied Materials. Suitable dopants that may be doped into the amorphous carbon layer includes As, B, P, H, N, and the like. In one embodiment depicted herein, the hardmask layer 402 may be an amorphous carbon layer with nitrogen dopants doped therein. In one embodiment, the hardmask layer 402 may have a thickness between about 100 Å and about 1000 Å.

In one embodiment, the hardmask layer 402 may be formed by a chemical vapor deposition (CVD), atomic layer deposition (ALD), cyclical layer deposition (CLD), physical vapor deposition (PVD), or the like as needed. In one particular embodiment, an inert gas, such as argon (Ar) or helium (He) gas, is supplied with the hydrocarbon compound, such as propane (O₃H₆) or acetylene, into the process chamber during the deposition process to form the hardmask layer 402 as an amorphous carbon layer.

At block 306, a planarization layer 404 may then be formed over the hardmask layer 402, as shown in FIG. 4C. The planarization layer 404 may be an organic polymer material spin-on-coated onto the hardmask layer 402. The planarization layer 404 may be spin-on-coated onto a non-planar substrate surface (i.e., the upper surface of the hardmask layer 402) with a sufficient thickness to create a substantially planar top surface 452 for the planarization layer 404. In one embodiment, the organic polymer material suitable for forming the planarization layer 404 includes a hydrocarbon containing material. Suitable examples of the hydrocarbon material include photoresist material, spin-on-glass (SOG) materials, and the like. In one example, the photoresist material may be a positive tone photoresist, a negative tone photoresist, a UV lithography photoresist, an I-line photoresist, an G-line photoresist, an e-beam resist (for example, a chemically amplified resist (CAR)) or other suitable photoresist.

In one embodiment, the planarization layer 404 may be coated onto the hardmask layer 402 with a thickness between about 20 nm and about 800 nm, for example between about 100 nm and about 400 nm. It is believed that the organic polymer materials provided for the planarization layer 404 may have a self-leveling planarization property so as to be coated onto the hardmask layer 402 to evenly cover the uneven topography of the structures formed on the substrate. By doing so, uneven topographic surface from the substrate 100 may be covered with a planarized or flattened top surface 452 to facilitate the subsequent photolithographic process so as to transfer features into the structures on the substrate 100 with accurate and precise dimension control.

In one embodiment, the planarization layer 404 may be spin-coated onto the substrate surface. In another embodiment, the planarization layer 404 may also be coated onto the substrate using injection, spray deposition system, spray deposition system, aerosol deposition (AD) process, aerojet, nanoparticles spray from solution, spray CVD, ink-jet, meniscus coating, dip coating, electroplating, spray coating, electrospraying, screen printing, or by other suitable techniques as needed.

After the planarization layer 404 is deposited onto the substrate 100, a baking or a heating process may be performed to harden the planarization layer 404. The substrate 100 may be placed on an oven or a hot plate to provide a temperature sufficiently high enough to cure the planarization layer 404 and have the planarization layer 404 reflow to its top surface 452 into a substantially planar form if needed.

At block 308, after the planarization layer 404 is disposed on the substrate 100 to provide the planar top surface 452, a patterned photoresist layer 408 may then formed on the substrate 100 defining openings 454 in the patterned photoresist layer 408 to expose a portion 414, such as the second type doped device region 410, of the planarization layer 404 for etching during the subsequent processes, as shown in FIG. 4D. An optional anti-reflective coating layer 406 (ARC layer) may be formed between the photoresist layer 408 and the planarization layer 404 to facilitate transfer the features into the planarization layer 404 along with the hardmask layer 402. The optional hardmask layer 406 may include side ARC layer that comprises silicon or a carbon mask, or in combination. Different materials may have different etchants for etching. The patterned photoresist layer 408 may be formed on the substrate 100 to expose any desired region of the substrate, including the first type doped device region 412, the second type doped device region 410 or any suitable places on the substrate as needed for different device requirements.

It is noted that the patterned photoresist layer 408 may be formed on the substrate utilizing any suitable photolithography and etching process as needed.

At block 310, a portion of the planarization layer 404 (e.g., also the optional ARC layer 406) along with the underlying hardmask layer 402 exposed by the patterned photoresist layer 408 are removed from the substrate 100, as shown in FIG. 4E. An etching process may be utilized to remove the portion of the planarization layer 404 along with the underlying hardmask layer 402, exposing surfaces 416, 418 of the underlying semiconductor fins 152 and the STI structure 104 for an implantation process, which will be described later with reference to FIG. 4G. During the etching process, the patterned photoresist layer 408, the optional ARC layer 406 and a portion of the planarization layer 404 protected by the patterned photoresist layer 408 may be consumed, leaving partial of the planarization layer 404 (e.g., protected under the patterned photoresist layer 408) remained on the substrate 100 after the etching process.

In one embodiment, the etching process as performed at block 310 may be a single etching step process or a multiple steps etching process. In the embodiment wherein a single etching step process is utilized, the etching process is selected to have a high etching capability to etch both the planarization layer 404 and the underlying hardmask layer 402 in a single step in a single processing chamber. In another embodiment wherein a multiple etching step process is utilized, the planarization layer 404 and the hardmask layer 402 may be etched individually using different process parameters in a single chamber or in different chambers.

In one embodiment, the planarization layer 404 and the hardmask layer 402 is one-step etched using the same process precursors and process parameters. The etching process may be performed by supplying a gas mixture into a processing chamber, such as the process chamber 200 depicted in FIG. 3. The gas mixture includes at least one oxygen containing gas to anisotropically etch the planarization layer 404 and the hardmask layer 402 disposed on the substrate 100. A RF power may be applied in the gas mixture to form a plasma to etch the planarization layer 404 and the hardmask layer 402 so as to obtain a vertical etching profile of feature 454 formed in the planarization layer 404 and the hardmask layer 402. In one embodiment, the RF power may include a RF source power at a frequency at about 162 MHz and optionally a RF bias power at a frequency of about 60 MHz.

During processing, oxygen containing gas may be supplied to etch the planarization layer 404 and the hardmask layer 402. As the planarization layer 404 and the hardmask layer 402 are likely carbon based materials, oxygen containing gas may be utilized to etch the planarization layer 404 and the hardmask layer 402. A carrier gas, or some other gases may also be added into the gas mixture to assist carrying gas into the processing chamber for processing and promote completed reaction. Suitable examples of the carrier gas include N₂, O₂, N₂O, NO₂, NH₃, H₂O, H₂, O₃, and the like. In an exemplary embodiment, the fluorine and carbon based gases used in the gas mixture is O₂ and N₂ to etch the planarization layer 404 and the hardmask layer 402.

Alternatively, the gas mixture includes at least one fluorine and carbon based gas. The fluorine and carbon based gases are dissociated as reactive etchants by the plasma formed from the gas mixture. The fluorine ions dissociated from fluorine and carbon based gases in the gas mixture may react with and attack the planarization layer 404 and the hardmask layer 402 through the opening features 454 defined by the patterned photoresist layer 408. Suitable examples of the fluorine and carbon based gases may include C₄F₆, C₄F₈, C₂F₂, CF₄, CHF₃, C₂F₆, C₄F₆, C₅F₈, CH₂F₂, SF₆, NF₃, O₂ and N₂ and the like. In an exemplary embodiment, the fluorine and carbon based gases used in the gas mixture is O₂ and N₂ to etch the planarization layer 404 and the hardmask layer 402. A carrier gas, or some other gases may also be added into the gas mixture to assist carrying gas into the processing chamber for processing and promote completed reaction. Suitable examples of the carrier gas include N₂, O₂, N₂O, NO₂, NH₃, H₂O, H₂, O₃, and the like. In one embodiment,

An inert gas may be optionally supplied with the gas mixture to assist carrying the gas mixture into the etch chamber. Suitable examples of the inert gases include N₂, Ar, He, Xe and Kr gas.

Several process parameters are regulated while the etching gas mixture is supplied into the etch chamber applying the RF power. In one embodiment, the chamber pressure is regulated between about 5 mTorr to about 400 mTorr, for example, at about 40 mTorr. The RF source power of about 200 Watts to about 3000 Watts may be applied to an capacitively coupled antenna source to maintain a plasma inside the etch chamber. The RF bias power of about 200 Watts to about 10000 Watts may be applied to the processing chamber. The fluorine based gas may be flowed into the chamber at a rate between about 30 sccm to about 300 sccm. A substrate temperature is maintained between about −10 degrees Celsius to about 60 degrees Celsius.

At block 312, after the portion of the planarization layer 404 along with the underlying hardmask layer 402 disposed in the second type doped device region 410 is removed, the remaining portion of the planarization layer 404 disposed in the first type doped device region 412 may be removed from the substrate, as shown in FIG. 4F, exposing the patterned hardmask layer 402 as an ion implantation mask for the subsequent ion implantation process. In one embodiment, the planarization layer 404 may be removed by an ash process using oxygen containing gas to remove the remaining portion of the planarization layer 404 from the substrate 100. As the removal of the planarization layer 404 at block 312 does not require high directionality and selectivity (e.g., the film properties between the organic materials of the planarization layer 404 and the materials from the hardmask layer 402 and the underlying semiconductor fins 102, 152 and adjacent STI structures 104 are very different), an isotropic etching process, such as an ash process, is then utilized in this step to remove the remaining planarization layer 404 from the substrate 100 in the first type doped device region 412.

In one embodiment, the ashing process is performed by supplying an ash gas mixture including at least one of an oxygen containing gas or a hydrogen containing gas or an inert gas into the processing chamber, such as the processing chamber 200, to react with the remaining planarization layer 404 from the substrate 100. The oxygen containing gas, the hydrogen containing gas or an inert gas supplied from the ash gas mixture forms carbon oxide gas, carbon hydrogen gas or other carbon containing byproducts with the remaining planarization layer 404, which can be pumped out of the chamber. In one embodiment, the ash gas mixture that may be utilized to perform the ash process includes O₂, H₂, N₂, H₂O, He, Ar, O₃, and the like.

During the ash process, several process parameters may be regulated to control the ash process. In one exemplary embodiment, a process pressure in the vacuum processing chamber 319 is regulated between about 10 mTorr to about 2000 mTorr, for example, at about 80 mTorr. A RF source power may be applied to maintain a plasma in the etching gas mixture. For example, a power of about 100 Watts to about 200 Watts may be applied to maintain a plasma inside the vacuum processing chamber 319. The ash gas mixture may be flowed into the chamber at a rate between about 20 sccm to about 5000 sccm. A substrate temperature is maintained between about 15 degrees Celsius to about 300 degrees Celsius.

At block 314, after the patterned hardmask layer 402 is exposed on the substrate 100, an ion implantation process may then be performed to selectively implant ions into only regions, such as the second type doped device region 410, uncovered by the patterned hardmask layer 402, as shown in arrows 420 depicted in FIG. 4G. The patterned hardmask layer 402 may efficiently protect the portion of the first type doped device region 412 covered by the patterned hardmask layer 402 from ions implanted thereto while exposing the portion of the second type doped device region 410 uncovered by the patterned hardmask layer 402 to have desired ions implanted thereto. It is believed that the patterned hardmask layer 402 has film properties that can efficiently block/shield the ions during the ion implantation process from penetrating into the substrate 100. As discussed above, in one embodiment, the hardmask layer 402 described herein is an amorphous carbon layer, a doped amorphous carbon layer, or the like. The ions that may be doped into the substrate 100 utilizing the hardmask layer 402 as an implanting mask are at least one of n-type dopants, such as As dopant, into the fin structures in the substrate or p-type dopants, such as B dopant, for the substrate. After the ion implantation process is completed, the hardmask layer 402 remained on the substrate may be removed from the substrate 100.

Thus, methods for forming a patterned hardmask layer on a semiconductor substrate utilized as an ion implanting mask are provided herein. The patterned hardmask layer may utilize a planarization layer disposed thereon during a hardmask patterning process to as to provide a good planar surface during a lithography process so as to assist transfer features into the planarization layer and the hardmask layer more accurately and precisely. By doing so, the hardmask layer may be successfully patterned utilizing the features transferred from the planarization layer with good profile and dimension control to as to assist providing a good ion implantation mask during a subsequent ion implantation process. Thus, an improved hardmask layer patterning process to obtain good features profile for small dimension, particularly for applications in semiconductor fin field effect transistors (FinFET), is obtained.

While the foregoing is directed to embodiments of the present invention, other and further embodiments of the invention may be devised without departing from the basic scope thereof, and the scope thereof is determined by the claims that follow.

1. A method of patterning a hardmask layer disposed on a substrate comprising:
forming a planarization layer over a hardmask layer disposed on a substrate;
disposing a patterned photoresist layer over the planarization layer;
patterning the planarization layer and the hardmask layer uncovered by the patterned photoresist layer in a processing chamber, exposing a first portion of the underlying substrate; and
removing the planarization layer from the substrate.

2. The method of claim 1, wherein pattering the planarization layer and the hardmask layer further comprising:
drying etching the planarization layer and the hardmask layer uncovered by the patterned photoresist layer in the processing chamber.

3. The method of claim 1, wherein pattering the planarization layer and the hardmask layer further comprising:
anisotropically patterning the planarization layer and the hardmask layer uncovered by the patterned photoresist layer in one processing chamber.

4. The method of claim 1, wherein removing the planarization layer from the substrate further comprises:
maintaining a portion of the hardmask layer on the substrate uncovered by the patterned photoresist layer on the substrate, covering a second portion of the underlying substrate while exposing the first portion of the underlying substrate.

5. The method of claim 1, wherein removing the planarization layer from the substrate further comprises:
performing an ash process to strip the planarization layer from the substrate.

6. The method of claim 1, further comprising:
performing an ion implantation process to implant ions into the exposed first portion of the underlying substrate using the hardmask layer remained on the substrate as an ion implantation mask.

7. The method of claim 1, wherein forming the planarization layer over the hardmask layer further comprises:
spin-on-coating the planarization layer on the hardmask layer.

8. The method of claim 1, wherein the planarization layer is an organic polymer material.

9. The method of claim 8, wherein the organic polymer material is selected from a group consisting of photoresist material and spin-on-glass (SOG) materials.

10. The method of claim 1, wherein the hardmask layer is an amorphous carbon layer or a doped amorphous carbon layer.

11. The method of claim 10, wherein the doped amorphous carbon layer has dopants doped therein, wherein the dopants is selected from a group consisting of As, H, B, N.

12. The method of claim 1, wherein the substrate includes a plurality of semiconductor fins formed thereon isolated by a plurality of shallow trench isolation structures.

13. The method of claim 1, wherein forming the planarization layer over the hardmask layer further comprises:
providing a planar surface on the substrate to allow the patterned photoresist layer to be formed thereon.

14. A method of patterning a hardmask layer disposed on a substrate comprising:
forming a hardmask layer on a substrate, wherein the substrate includes a plurality of semiconductor fins formed thereon isolated by a plurality of shallow trench isolation structures;
forming a planarization layer over the hardmask layer disposed on a substrate to form a substantially planar upper surface on the planarization layer; and
patterning the planarization layer and the hardmask layer utilizing a patterned photoresist layer disposed over the substantially planar upper surface on the planarization layer until a portion of the semiconductor fins formed on the substrate is exposed.

15. The method of claim 14, wherein forming the planarization layer further comprising:
spin-on-coating the planarization layer on the hardmask layer.

16. The method of claim 14, wherein the planarization layer is an organic polymer material selected from a group consisting of photoresist material and spin-on-glass (SOG) materials.

17. The method of claim 14, wherein the hardmask layer is an amorphous carbon layer or a doped amorphous carbon layer.

18. The method of claim 14, further comprising:
removing the planarization layer remained on the substrate exposing a portion of the hardmask layer remained on the substrate; and
utilizing the hardmask layer remained on the substrate as an ion implantation mask during an ion implantation process.

19. The method of claim 14, wherein patterning the planarization layer and the hardmask layer further comprising:
anisotropically etching the planarization layer and the hardmask layer.

20. A method of patterning a hardmask layer disposed on a substrate comprising:
spin-coating a planarization layer over a hardmask layer on a substrate, wherein the substrate includes a plurality of semiconductor fins formed thereon isolated by a plurality of shallow trench isolation structures;
anisotropically patterning a portion of the planarization layer and a portion of the hardmask exposed by a patterned photoresist layer disposed on the planarization layer to expose a portion of the semiconductor fins formed on the substrate;
removing the planarization layer from the substrate exposing the hardmask layer remained on the substrate; and
performing an ion implantation process utilizing the hardmask layer remained on the substrate as an ion implantation mask.
